(19) United States
(12) Patent Application Publication
(10) Pub. No.: US 2015/0087097 A1
(43) Pub. Date: Mar. 26, 2015

(54) METHOD FOR MANUFACTURING A LIGHT-EMITTING DIODE

(71) Applicant: LEXTAR ELECTRONICS CORPORATION, HSINCHU (TW)

(72) Inventors: Po-Hung TSOU, New Taipei City (TW); Tzu-Hung CHOU, Taoyuan County (TW)

(73) Assignee: LEXTAR ELECTRONICS CORPORATION, HSINCHU (TW)

(21) Appl. No.: 14/276,938

(22) Filed: May 13, 2014

(30) Foreign Application Priority Data
Sep. 26, 2013 (TW) 102134692

(51) Int. Cl. H01L 33/00; H01L 33/42

(52) U.S. Cl. CPC H01L 33/007; H01L 33/42; H01L 2933/0016
USPC 438/46

(57) ABSTRACT

The present disclosure provides a method for manufacturing a light-emitting diode, including: providing a substrate; forming a first semiconductor layer over the substrate; forming an active layer over the first semiconductor layer; forming a second semiconductor layer over the active layer; removing a portion of the second semiconductor layer and a portion of the active layer to expose a portion of the first semiconductor layer; conform to depositing a transparent conductive layer; forming a patterned mask layer over the transparent conductive layer; performing a wet etch process to remove a portion of the transparent conductive layer; performing a dry etch process to completely remove the portion of the transparent conductive layer not covered by the patterned mask layer; removing the patterned mask layer; and forming a first electrode and a second electrode.

### CROSS REFERENCE TO RELATED APPLICATIONS

This application claims priority of Taiwan Patent Application No. 102134692, filed on Sep. 26, 2013, the entirety of which is incorporated by reference herein.

### BACKGROUND

1. Technical Field

The disclosure relates to a method for manufacturing a light-emitting device, and in particular to a method for manufacturing a light-emitting diode.

2. Description of the Related Art

A light-emitting diode is formed by forming an active layer over a substrate and depositing different conductive and semi-conductive layers over the substrate. The recombination radiation of electron and hole may produce electromagnetic radiation (such as light) through the current at the p-n junction. For example, in the forward bias p-n junction formed by direct band gap materials such as GaAs or GaN, the recombination of electron and hole injected into the depletion region results in electromagnetic radiation such as light. The aforementioned electromagnetic radiation may lie in the visible region or the non-visible region. Materials with different band gaps may be used to form light-emitting diodes with different colors. Besides, electromagnetic radiation that lays in the non-visible region may be transferred to visible light through phosphorous lenses.

Since mass production has become the tendency of the light-emitting diode industry recently, any increase in the yield of manufacturing light-emitting diodes will reduce costs and result in huge economic benefits. However, it is very difficult to further increase the yield in a manufacturing process which already has a high manufacturing yield. Sometimes, to increase the yield, manufacturing processes are modified substantially, or many manufacturing steps are added. Although the yield may be increased through the above methods, the cost is increased in the meantime, which is not cost-effective. Therefore, a simple method for manufacturing the light-emitting device, which can effectively increase the yield without adding too many manufacturing steps or too much cost, and which has a high manufacturing compatibility, is needed.

### SUMMARY

The present disclosure provides a method for manufacturing a light-emitting diode, comprising: providing a substrate; forming a first semiconductor layer over the substrate, wherein the first semiconductor layer has a first conductivity type; forming an active layer over the first semiconductor layer; forming a second semiconductor layer over the active layer, wherein the second semiconductor layer has a second conductivity type different from the first conductivity type; removing a portion of the second semiconductor layer and a portion of the active layer to expose a portion of the first semiconductor layer; depositing a transparent conductive layer along the top surface and sidewalls of the second semiconductor layer and over the exposed portion of the first semiconductor layer; forming a patterned mask layer over the transparent conductive layer to cover a portion of the transparent conductive layer disposed over the second semiconductor layer; performing a wet etch process to remove a portion of the transparent conductive layer not covered by the patterned mask layer; after the wet etch process, performing a dry etch process to completely remove the portion of the transparent conductive layer not covered by the patterned mask layer; removing the patterned mask layer; forming a first electrode over the transparent conductive layer; and forming a second electrode over the portion of the first semiconductor layer not covered by the active layer.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIGS. 1-7 are cross-sectional views of a light-emitting diode at various manufacturing stages in accordance with some embodiments of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In this specification, expressions such as “overlying the substrate”, “above the layer”, or “on the film” simply denote a relative positional relationship with respect to the surface of a base layer, regardless of the existence of intermediate layers. Accordingly, these expressions may indicate not only the direct contact of layers, but also, a non-contact state of one or more laminated layers. It is noted that, in the accompanying drawings, like and/or corresponding elements are denoted by like reference numerals.

In this specification, relative expressions are used. For example, “lower”, “bottom”, “higher” or “top” are used to describe the position of an element relative to another. It should be appreciated that if a device is flipped upside down, an element at a “lower” side will become an element at a “higher” side.

Unless defined otherwise, all technical and scientific terms used herein have the same meaning as commonly understood to one of ordinary skill in the art to which this invention belongs. It should be appreciated that, in each case, the term, which is defined in a commonly used dictionary, should be interpreted as having a meaning that conforms to the relative skills and the background or the context of the present disclosure, and should not be interpreted by an idealized or overly formal manner unless defined otherwise.

The terms “about” and “substantially” typically mean +/−20% of the stated value, more typically +/−10% of the stated value and even more typically +/−5% of the stated value. The stated value of the present disclosure is an approximate value. When there is no specific description, the stated value includes the meaning of “about” or “substantially”.

The method for manufacturing the light-emitting diode provided in the present disclosure performs a dry etch after the wet etch process which etches the transparent conductive layer to completely remove the remaining transparent conductive layer to increase the current leakage yield, which in turn increases the total yield of the manufacturing process of the light-emitting diode.

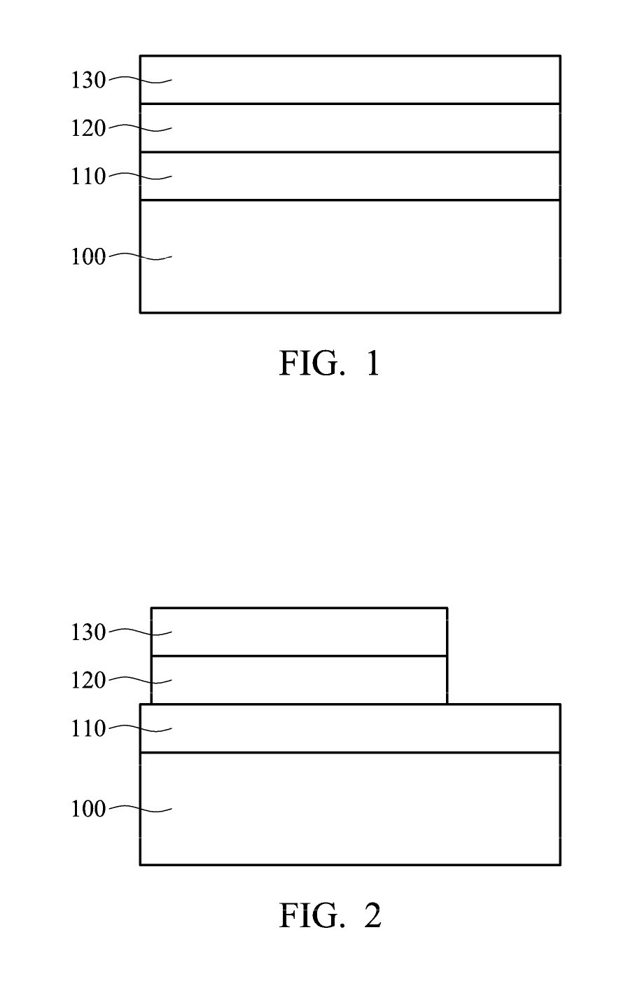

Referring to FIG. 1, a substrate 100 is provided. The substrate 100 may include a Si substrate, a SiC substrate, a sapphire substrate or any other suitable substrates. Then a first semiconductor layer 110 is formed over the substrate 100. The first semiconductor layer 110 has a first conductivity type. The first semiconductor layer 110 may include, but is not limited to, doped or undoped InₓAl_{y}Ga_{(1-x-y)}N, wherein 0≦x≦1, 0≦y≦1 and 0≦(x+y)≦1. For example, the first semiconductor layer 110 may include, but is not limited to, doped or undoped GaN, InN, AlN, InₓGa₍₁₋ₓ₎N, AlₓIn₍₁₋ₓ₎N, AlₓIn_{y}Ga_{(1-x-y)}N or any other suitable materials, wherein 0≦x≦1, 0≦y≦1 and 0≦(x+y)≦1. The first semiconductor layer 110 may be a P-type semiconductor layer or an N-type semiconductor layer, and may be formed by molecular beam epitaxy (MBE), metal organic chemical vapor deposition (MOCVD), hydride vapor phase epitaxy (HVPE), liquid phase epitaxy or any other suitable epitaxy process.

Still referring to FIG. 1, after forming the first semiconductor layer 110, an active layer 120 is formed over the first semiconductor layer 110. The active layer 120 may include, but is not limited to, homojunction, heterojunction, single-quantum well (SQW), multiple-quantum well (MQW) or any other suitable structures. In some embodiments of the present disclosure, the active layer 120 may include, but is not limited to, undoped N-type InₓGa₍₁₋ₓ₎N. In some embodiments of the present disclosure, the active layer 120 may include other materials such as AlₓIn_{y}Ga_{(1-x-y)}N. In addition, the active layer 120 may include a multiple-quantum well structure with multiple-quantum layers (such as InGaN) and barrier layers (such as GaN) arranged alternately. In addition, the active layer 120 may be formed by metal organic chemical vapor deposition (MOCVD), molecular beam epitaxy (MBE), hydride vapor phase epitaxy (HVPE), liquid phase epitaxy or any other suitable chemical vapor deposition process. In some embodiments of the present disclosure, the total thickness of the active layer 120 may range from about 5 nm to 200 nm.

Still referring to FIG. 1A, after forming the active layer 120, a second semiconductor layer 130 is formed over the active layer 120. The second semiconductor layer 130 has a second conductivity type different from the first conductivity type. The second semiconductor layer 130 may include, but is not limited to, doped or undoped InₓAl_{y}Ga_{(1-x-y)}N, wherein 0≦x≦1, 0≦y≦1 and 0≦(x+y)≦1. For example, the second semiconductor layer 130 may include, but is not limited to, doped or undoped GaN, InN, AlN, InₓGa₍₁₋ₓ₎N, AlₓIn₍₁₋ₓ₎N, AlₓIn_{y}Ga_{(1-x-y)}N or any other suitable materials, wherein 0≦x≦1, 0≦y≦1 and 0≦(x+y)≦1. The second semiconductor layer 130 may be a P-type semiconductor layer or an N-type semiconductor layer, and may be formed by molecular beam epitaxy (MBE), metal organic chemical vapor deposition (MOCVD), hydride vapor phase epitaxy (HVPE), liquid phase epitaxy or any other suitable epitaxy process.

Next, as illustrated in FIG. 2, a portion of the second semiconductor layer 130 and a portion of the active layer 120 are removed to expose a portion of the first semiconductor layer 110. Removal of the portion of the second semiconductor layer 130 and the portion of the active layer 120 may be accomplished by forming a patterned photoresist layer (not shown) over the substrate 100 to expose the portion of the second semiconductor layer 130 and the portion of the active layer 120 which are to be removed. The patterned photoresist layer may be formed by photolithography, immersion lithography, ion-beam writing, or any other suitable methods. For example, photolithography may include, but is not limited to, spin-on coating, soft baking, exposure, post exposure baking, development, cleaning, drying and other suitable processes. The portion of the second semiconductor layer 130 and the portion of the active layer 120 may be removed by a dry etching process, a wet etching process, or a combination thereof. For example, the wet etching process may include exposure to a hydroxide-containing solution (such as ammonium hydroxide), deionized water and/or other suitable etchants. The dry etching process may include capacitively coupled plasma etching, inductively-coupled plasma etching, helicon plasma etching, electron cyclotron resonance plasma etching, or any other suitable dry etching processes. The etching process may be stopped after a period of time to leave a portion of the second semiconductor layer 130 and a portion of the active layer 120. Therefore, a portion of the second semiconductor layer 130 and a portion of the active layer 120 are removed to expose a portion of the first semiconductor layer 110, and the patterned photoresist layer (not shown) may be removed by a wet stripping process, plasma ashing, or a combination thereof.

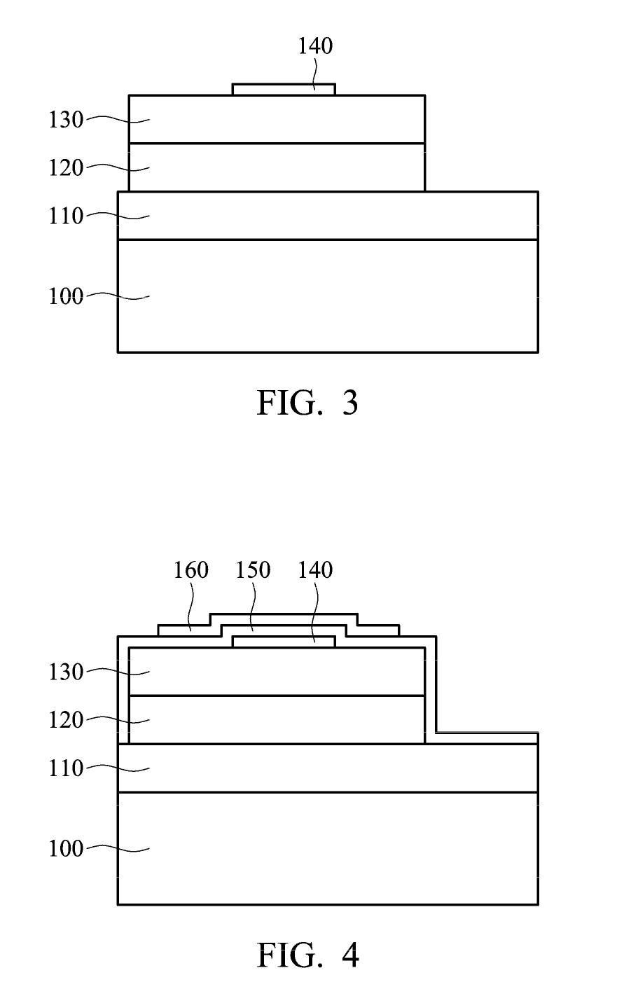

Next, as illustrated in FIG. 3, after removing a portion of the second semiconductor layer 130 and a portion of the active layer 120, a patterned current blocking layer 140 is optionally formed over the second semiconductor layer 130. The patterned current blocking layer 140 may include, but is not limited to, insulating material such as silicon oxide, silicon nitride or any other suitable materials. The patterned current blocking layer 140 may be disposed under the subsequent electrode of the light-emitting diode to prevent light from being emitting from the active layer 120 corresponding to the electrode and being absorbed or reflected by the electrode, which in turn may further increase the light extraction efficiency of the light-emitting diode.

Next, as illustrated in FIG. 4, a transparent conductive layer 150 is deposited along the top surface and the sidewalls of the second semiconductor layer 130 and over the exposed portion of the first semiconductor layer 110. If the patterned current blocking layer 140 is over the second semiconductor layer 130, the transparent conductive layer 150 is disposed over the patterned current blocking layer 140. The transparent conductive layer 150 may be deposited by chemical vapor deposition (CVD), metal organic chemical vapor deposition (MOCVD), physical vapor deposition (PVD), atomic layer deposition, pulsed laser deposition, or any other suitable methods. The transparent conductive layer 150 may include, but is not limited to, tin oxide (TO), indium tin oxide (ITO), indium zinc oxide (IZO), indium gallium zinc oxide (IGZO), indium tin zinc oxide (ITZO), antimony tin oxide (ATO), antimony zinc oxide (AZO), a combination thereof, or any other suitable materials.

Then, still referring to FIG. 4, a patterned mask layer 160 is formed over the transparent conductive layer 150 to cover a portion of the transparent conductive layer 150 disposed over the second semiconductor layer 130 (or over the second semiconductor layer 130 and the patterned current blocking layer 140). The patterned mask layer 160 may include, but is not limited to, patterned photoresist or patterned hard mask such as silicon oxide, silicon nitride or silicon oxide nitride. In some embodiments of the present disclosure, as illustrated in FIG. 4, the patterned mask layer 160 merely covers a portion of the transparent conductive layer 150 disposed over the second semiconductor layer 130. In other embodiments of the present disclosure, the patterned mask layer 160 may completely cover the transparent conductive layer 150 disposed over the second semiconductor layer 130.

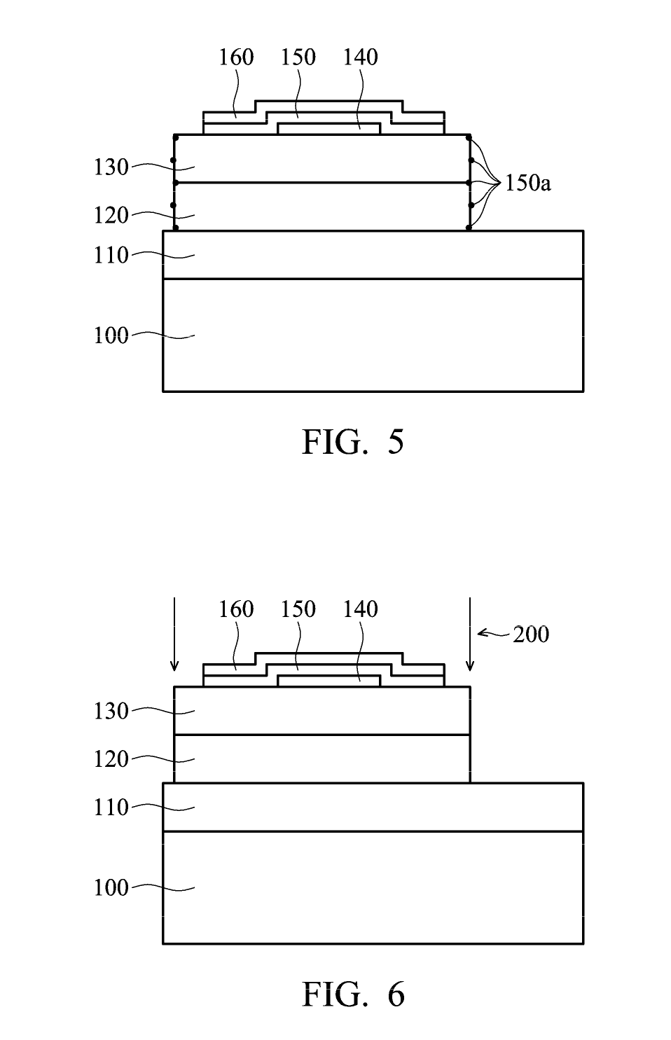

Next, as illustrated in FIG. 5, a wet etch process is performed to remove the portion of the transparent conductive layer 150 not covered by the patterned mask layer 160. The wet etching process may include, but is not limited to, exposure to hydroxide-containing solution (such as ammonium hydroxide), deionized water and/or other suitable etchant.

In general manufacturing processes of light-emitting diodes, if the etching time of the wet etching process is too long, over etching will result and the transparent conductive layer 150 will be side-etched. The side-etching of the transparent conductive layer 150 will reduce the surface area of the transparent conductive layer 150, which in turn lowers the yield and increases the driving voltage of the light-emitting diode. Therefore, those skilled in the art will control the etching time of the wet etching process to prevent over etching. However, the Applicant analyzes the light-emitting diode manufactured through the aforementioned general manufacturing process by scanning electron microscopy (SEM) and energy dispersive X-ray (EDX) and discovers that the control of the etching time of the wet etching process for preventing over etching will result in a portion of the transparent conductive layer 150 remaining over the sidewalls of the second semiconductor layer 130. As illustrated in FIG. 5, the transparent conductive layer 150a is the transparent conductive layer 150 remaining on the sidewalls of the second semiconductor layer 130. The transparent conductive layer 150a generates leaked current I such that the current may flow directly from the transparent conductive layer 150 to the first semiconductor layer 110, which in turn lowers the luminous efficiency of the light-emitting diode and the current leakage yield and total yield of the manufacturing process. Therefore, Applicant discovers the aforementioned issues and performs a dry etching process after the wet etching process to solve the issues.

As illustrated in FIG. 6, after completing the wet etch process which etches the transparent conductive layer 150, a dry etch process 200 is performed to completely remove the portion of the transparent conductive layer 150 not covered by the patterned mask layer 160. In some embodiments of the present disclosure, the wet etch process removes the transparent conductive layer 150 over the top surface of the first semiconductor layer 110 and the top surface of the second semiconductor layer 130 and leaves a portion of the transparent conductive layer 150a over the sidewalls of the second semiconductor layer 130. The dry etch process 200 removes the remaining portion of the transparent conductive layer 150a over the sidewalls of the second semiconductor layer 130. The dry etch process 200 may include, but is not limited to, capacitively coupled plasma etching, inductively-coupled plasma etching, helicon plasma etching, electron cyclotron resonance plasma etching or any other suitable dry etch processes. The dry etch process 200 employs a process gas, which may include, but is not limited to, inert gas, fluorine-containing gas, chlorine-containing gas, bromine-containing gas, iodine-containing gas, a combination thereof or any other suitable gases. In some embodiments of the present disclosure, the processing gas may include, but is not limited to, Ar, CF₄, SF₆, CH₂F₂, CHF₃, C₂F₆, Cl₂, CHCl₃, CCl₄, HBr, CHBr₃, a combination thereof or any other suitable gases. In some embodiments, the processing gas may further include BF₃, BCl₃ or a combination thereof. Note that BF₃, BCl₃ may increase the anisotropy of the dry etch process 200 such that the remaining portion 150a of the transparent conductive layer may be removed thoroughly in the dry etch process 200. Since the remaining transparent conductive layer may be removed thoroughly by the dry etch process 200, the current leakage yield and the total yield of the manufacturing process of the light-emitting diode may be increased. The method for manufacturing the light-emitting diode in the present disclosure may be easily combined with the conventional manufacturing process, therefore it has high manufacturing compatibility and can effectively increase the yield without adding too many manufacturing steps or too much cost.

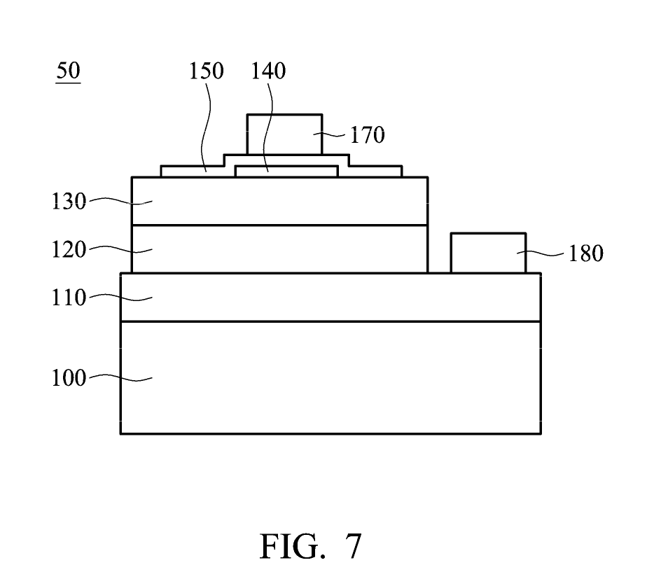

Next, as illustrated in FIG. 7, after performing the dry etch process 200, the patterned mask layer 160 is removed. The patterned mask layer 160 may be removed by a wet stripping process, plasma ashing or a combination thereof. Then, a first electrode 170 is formed over the patterned transparent conductive layer 150, and a second electrode 180 is formed over the portion of the first semiconductor layer 110 which is not covered by the active layer 120 to complete the light-emitting diode 50. Note that, when the light-emitting diode 50 includes the patterned current blocking layer 140 between the second semiconductor layer 130 and the transparent conductive layer 150, the first electrode 170 is disposed over the patterned current blocking layer 140. In other words, the patterned current blocking layer 140 is disposed under the first electrode 170.

The first electrode 170 and the second electrode 180 may independently include a single layer or multiple layers of Au, Cr, Ni, Pt, Ti, Al, Ir, Rh, a combination thereof, or other metal materials with good conductivity. The first electrode 170 and the second electrode 180 may be formed by forming a metal layer over the light-emitting diode 50, then processing the metal layer into the electrodes by a photolithography and etching process.

In some embodiments, the method for manufacturing the light-emitting diode in the present disclosure may increase the total yield by about 1%-3%, for example, 1%-2%.

Table 1 shows the average current leakage yield and average total yield of the light-emitting diodes manufactured by four production lines according to the comparative examples and the embodiments of the present disclosure, respectively. The manufacturing steps of the embodiments are the same as the comparative examples except an additional dry etching process is added in the embodiments. As shown in Table 1, the average current leakage yield is increased by 0.99% and the average total yield is increased by 1.21% in the embodiments of the present disclosure

| Current leakage yield | | | Total yield | | |
|---|---|---|---|---|---|
| Comparative | | | Comparative | | |
| examples | Embodiments | Yield increase | examples | Embodiments | Yield increase |
| 1-4 (%) | 1-4 (%) | (%) | 1-4 (%) | 1-4 (%) | (%) |
| 96.97 | 97.96 | 0.99 | 96.58 | 97.79 | 1.21 |

In summary, the method for manufacturing the light-emitting diode provided in the present disclosure performs an additional dry etch to completely remove the remaining transparent conductive layer to increase the current leakage yield, which in turn increases the total yield of the manufacturing process of the light-emitting diode. The method for manufacturing the light-emitting diode in the present disclosure may be easily combined with the conventional manufacturing process, therefore it has high manufacturing compatibility and can effectively increase the yield without adding too many manufacturing steps or too much cost.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A method for manufacturing a light-emitting diode, comprising:
providing a substrate;
forming a first semiconductor layer over the substrate, wherein the first semiconductor layer has a first conductivity type;
forming an active layer over the first semiconductor layer;
forming a second semiconductor layer over the active layer, wherein the second semiconductor layer has a second conductivity type different from the first conductivity type;
removing a portion of the second semiconductor layer and a portion of the active layer to expose a portion of the first semiconductor layer;
conform to depositing a transparent conductive layer over a top surface and sidewalls of the second semiconductor layer and over the exposed portion of the first semiconductor layer;
forming a patterned mask layer over the transparent conductive layer to cover a portion of the transparent conductive layer disposed over the second semiconductor layer;
performing a wet etch process to remove a portion of the transparent conductive layer not covered by the patterned mask layer;
after the wet etch process, performing a dry etch process to completely remove the portion of the transparent conductive layer not covered by the patterned mask layer;
removing the patterned mask layer;
forming a first electrode over the transparent conductive layer; and
forming a second electrode over the portion of the first semiconductor layer not covered by the active layer.

2. The method for manufacturing the light-emitting diode as claimed in claim 1, wherein the wet etch process removes the transparent conductive layer over a top surface of the first semiconductor layer and the top surface of the second semiconductor layer and leaves a portion of the transparent conductive layer over the sidewalls of the second semiconductor layer, and the dry etch process removes the remained portion of the transparent conductive layer over the sidewalls of the second semiconductor layer.

3. The method for manufacturing the light-emitting diode as claimed in claim 2, further comprising forming a patterned current blocking layer between the second semiconductor layer and the transparent conductive layer, wherein the patterned current blocking layer disposed under the first electrode.

4. The method for manufacturing the light-emitting diode as claimed in claim 1, wherein the dry etch process comprises capacitively coupled plasma etching, inductively-coupled plasma etching, helicon plasma etching or electron cyclotron resonance plasma etching.

5. The method for manufacturing the light-emitting diode as claimed in claim 4, wherein the dry etch process employs a process gas comprising inert gas, fluorine-containing gas, chlorine-containing gas, bromine-containing gas, iodine-containing gas or a combination thereof.

6. The method for manufacturing the light-emitting diode as claimed in claim 5, wherein the processing gas comprises Ar, CF₄, SF₆, CH₂F₂, CHF₃, C₂F₆, Cl₂, CHCl₃, CCl₄, HBr, CHBr₃ or a combination thereof.

7. The method for manufacturing the light-emitting diode as claimed in claim 6, wherein the processing gas further comprises BF₃, BCl₃ or a combination thereof.

8. The method for manufacturing the light-emitting diode as claimed in claim 1, wherein the transparent conductive layer comprises tin oxide (TO), indium tin oxide (ITO), indium zinc oxide (IZO), indium gallium zinc oxide (IGZO), indium tin zinc oxide (ITZO), antimony tin oxide (ATO), antimony zinc oxide (AZO) or a combination thereof.

9. The method for manufacturing the light-emitting diode as claimed in claim 1, wherein the substrate comprises a Si substrate, a SiC substrate or a sapphire substrate.

10. The method for manufacturing the light-emitting diode as claimed in claim 1, wherein each of the first semiconductor layer and the second semiconductor layer independently comprises InₓAl_{y}Ga_{(1-x-y)}N, wherein 0≦x<1, 0≦y<1 and 0≦(x+y)<1.
